(19) United States
(12) Patent Application Publication
(10) Pub. No.: US 2025/0079290 A1
(43) Pub. Date: Mar. 6, 2025

(54) WIRING SUBSTRATE AND SEMICONDUCTOR DEVICE

(71) Applicant: SHINKO ELECTRIC INDUSTRIES CO., LTD., Nagano (JP)

(72) Inventors: Yuki KOBAYASHI, Nagano (JP); Tomoo YAMASAKI, Nagano (JP)

(21) Appl. No.: 18/822,967

(22) Filed: Sep. 3, 2024

(30) Foreign Application Priority Data
Sep. 6, 2023 (JP) 2023-144376

(51) Int. Cl. H01L 23/498; H01L 23/00

(52) U.S. Cl. CPC H01L 23/49838; H01L 23/49811; H01L 23/49866; H01L 24/13; H01L 24/16; H01L 24/81; H01L 2224/13023; H01L 2224/16111; H01L 2224/16188; H01L 2224/81815

(57) ABSTRACT

A wiring substrate includes an insulating layer and a protruding electrode. The insulating layer has a recess formed in the upper surface of the insulating layer. The protruding electrode is partly buried in the insulating layer to protrude in the recess. The width of the protruding electrode is constant in a sectional view of the protruding electrode. The upper surface of the protruding electrode is positioned lower than the upper surface of the insulating layer.

### CROSS-REFERENCE TO RELATED APPLICATION

This application is based upon and claims priority to Japanese Patent Application No. 2023-144376, filed on Sep. 6, 2023, the entire contents of which are incorporated herein by reference.

### FIELD

A certain aspect of the embodiment discussed herein is related to wiring substrates and semiconductor devices.

### BACKGROUND

As semiconductor elements are becoming increasingly more functional, the pitch of electrodes in semiconductor elements is becoming narrower, so that the pitch of protruding electrodes to connect to semiconductor elements is required to be narrower in wiring substrates on which semiconductor elements are mountable (see, for example, Japanese Patent No. 6, 608,108).

### SUMMARY

According to an aspect, a wiring substrate includes an insulating layer and a protruding electrode. The insulating layer has a recess formed in the upper surface of the insulating layer. The protruding electrode is partly buried in the insulating layer to protrude in the recess. The width of the protruding electrode is constant in a sectional view of the protruding electrode. The upper surface of the protruding electrode is positioned lower than the upper surface of the insulating layer.

The object and advantages of the invention will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF DRAWINGS

FIG. 1 is a sectional view of a wiring substrate according to an embodiment;

FIGS. 2A through 2I are diagrams illustrating a process of manufacturing a wiring substrate according to the embodiment;

FIGS. 3A through 3D are diagrams illustrating a process of manufacturing a wiring substrate according to a comparative example;

FIGS. 4A through 4C are diagrams illustrating a process of manufacturing a semiconductor device according to the comparative example;

FIG. 5 is a sectional view illustrating a semiconductor device according to the embodiment; and

FIG. 6 is a sectional view of a wiring substrate according to a variation of the embodiment.

### DESCRIPTION OF EMBODIMENTS

As the pitch of protruding electrodes becomes narrower, adjacent protruding electrodes are more likely to be short-circuited when the protruding electrodes are connected to semiconductor elements.

According to an embodiment, a wiring substrate in which adjacent protruding electrodes are less likely to be short-circuited is provided.

One or more embodiments of the present invention are explained below with reference to the accompanying drawings. In the following, the same elements or configurations are referred to using the same reference numerals, and description thereof may be omitted.

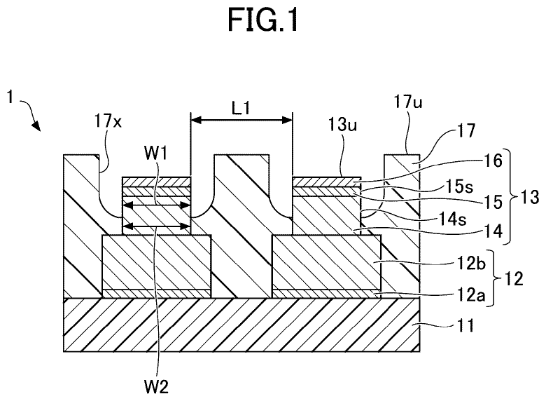

FIG. 1 is a sectional view of a wiring substrate according to an embodiment. Referring to FIG. 1, a wiring substrate 1 includes an insulating layer 11, a wiring layer 12, protruding electrodes 13, and an insulating layer 17.

According to this embodiment, for convenience of description, the insulating layer 17 side of the wiring substrate 1 is referred to “upper side”, and the insulating layer 11 side of the wiring substrate 1 is referred to as “lower side.” Furthermore, with respect to each part or element of the wiring substrate 1, a surface on the insulating layer 17 side is referred to as “upper surface” and a surface on the insulating layer 11 side is referred to as “lower surface.” The wiring substrate 1, however, may be used in an inverted position or oriented at any angle. Furthermore, a plan view refers to a view of an object taken in a direction normal to the upper surface of the insulating layer 17, and a planar shape refers to the shape of an object as viewed in a direction normal to the upper surface of the insulating layer 17.

The insulating layer 11 is, for example, an insulating layer that may be formed, using a build-up process, as an interlayer insulating layer for multilayer wiring. Accordingly, other wiring layers and other insulating layers may be stacked as underlayers of the insulating layer 11. In this case, via holes may be suitably provided in the insulating layer 11 and other insulating layers, and wiring layers may be connected via the via holes.

Examples of materials that may be used for the insulating layer 11 include non-photosensitive (thermosetting) epoxy insulating resins and polyimide insulating resins. Examples of materials that may be used for the insulating layer 11 may further include photosensitive epoxy resins and acrylic insulating resins. The thickness of the insulating layer 11 may be, for example, approximately 20 μm to approximately 40 μm. The insulating layer 11 may also include filler such as silica (SiO2).

The wiring layer 12 is formed on the insulating layer 11. The wiring layer 12 may have a structure in which an electroplating layer 12b is stacked on a seed layer 12a, for example. The seed layer 12a is, for example, a copper (Cu) layer of approximately 100 nm to approximately 350 nm in thickness. As the seed layer 12a, a laminate film in which a copper layer of approximately 100 nm to approximately 300 nm in thickness is stacked on a titanium layer of approximately 20 nm to approximately 50 nm in thickness may also be used. The electroplating layer 12b is, for example, a copper layer of approximately 10 μm to approximately 20 μm in thickness. Because the seed layer 12a is extremely thin, the thickness of the electroplating layer 12b may be regarded as the thickness of the entirety of the wiring layer 12.

The protruding electrodes 13, which may be hereinafter collectively referred to as “protruding electrode 13” where no distinction is made between the protruding electrodes 13, are formed in part of the upper surface of the wiring layer 12. The protruding electrode 13 may include a first metal layer 14, a second metal layer 15, and a third metal layer 16. The first metal layer 14 is stacked on the upper surface of the wiring layer 12. The second metal layer 15 is stacked on the upper surface of the first metal layer 14 without extending onto a side surface 14s of the first metal layer 14. That is, while the upper surface of the first metal layer 14 is covered with the second metal layer 15, the side surface 14s of the first metal layer 14 is not covered by and is exposed from the second metal layer 15. The third metal layer 16 is stacked on the upper surface of the second metal layer 15 without extending onto a side surface 15s of the second metal layer 15. That is, while the upper surface of the second metal layer 15 is covered with the third metal layer 16, the side surface 15s of the second metal layer 15 is not covered by and is exposed from the third metal layer 16.

The protruding electrode 13 may be formed of only the first metal layer 14 or may be formed of only the first metal layer 14 and the second metal layer 15.

The first metal layer 14 is, for example, a copper layer. The thickness of the first metal layer 14 is, for example, approximately 5 μm to approximately 10 μm. The second metal layer 15 is, for example, a nickel layer. The thickness of the second metal layer 15 is, for example, approximately 0.1 μm to approximately 3 μm. The third metal layer 16 includes, for example, a gold (Au) layer. The third metal layer 16 may be formed of only a gold layer or may be formed of a gold layer and a palladium (Pd) layer stacked on the gold layer. The thickness of the third metal layer 16 is, for example, approximately 0.01 μm to approximately 0.1 μm.

The insulating layer 17 is stacked on the upper surface of the insulating layer 11 to cover the upper surface and the side surface of the wiring layer 12 and part of the side surface of the protruding electrode 13. Recesses 17x, which may be hereinafter collectively referred to as “recess 17x” where no distinction is made between the recesses 17x, are formed in an upper surface 17u of the insulating layer 17 to have respective openings at the upper surface 17u of the insulating layer 17. In a sectional view, the joint of the side and the bottom of the recess 17x may be curved or rounded as illustrated in FIG. 1 or may be square or nearly square. In a plan view, the outer edge of the recess 17x is positioned outside the outer edge of the protruding electrode 13, that is, the entirety of the protruding electrode 13 is positioned within the recess 17x. There is a space between the entire side surface of part of the protruding electrode 13 protruding in the recess 17x and the inside surface (inner wall surface) of the recess 17x. The width of the space is, for example, approximately 0.5 μm to approximately 5 μm.

The protruding electrode 13 includes a part buried in the insulating layer 17 and the part protruding into the recess 17x. According to this embodiment, a lower part of the first metal layer 14 of the protruding electrode 13 is buried in the insulating layer 17, and an upper part of the first metal layer 14, the second metal layer 15, and the third metal layer 16 protrude into the recess 17x.

The protruding electrode 13 is, for example, cylindrical. In a sectional view of the protruding electrode 13 (for example, taken along a plane perpendicular to the upper surface 17u of the insulating layer 17), a width W1 of the part protruding in the recess 17x is equal to a width W2 of the part buried in the insulating layer 17. Here, being equal means that the larger is less than or equal to 1.1 times the smaller of the width W1 and the width W2. An upper surface 13u of the protruding electrode 13 is positioned lower than the upper surface 17u of the insulating layer 17. That is, the upper surface 13u of the protruding electrode 13 is closer to the bottom of the recess 17x than is the upper surface 17u of the insulating layer 17. According to this embodiment, the upper surface 13u of the protruding electrode 13 is the upper surface of the third metal layer 16. An interval L1 between the adjacent protruding electrodes 13 may be, for example, approximately 5 μm to approximately 30 μm.

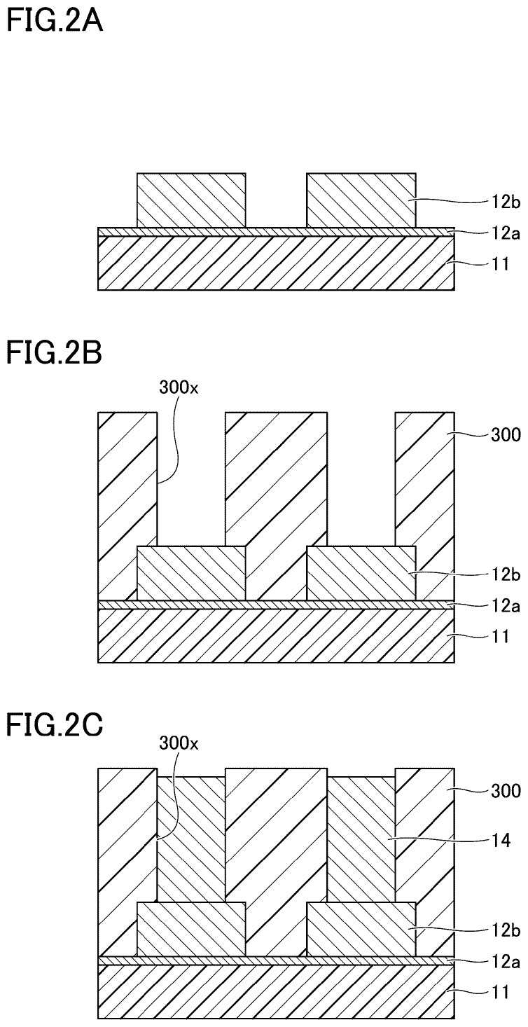

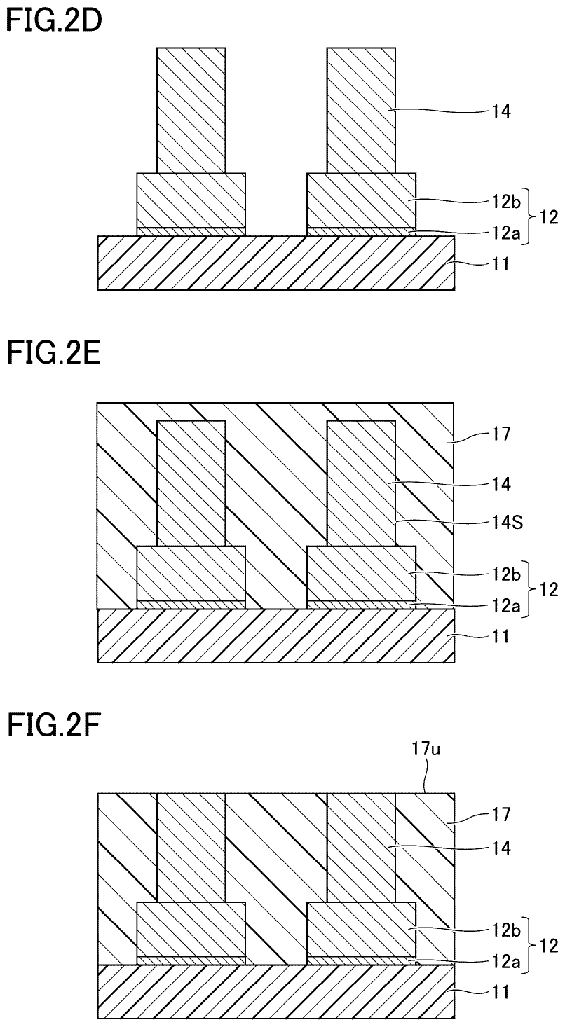

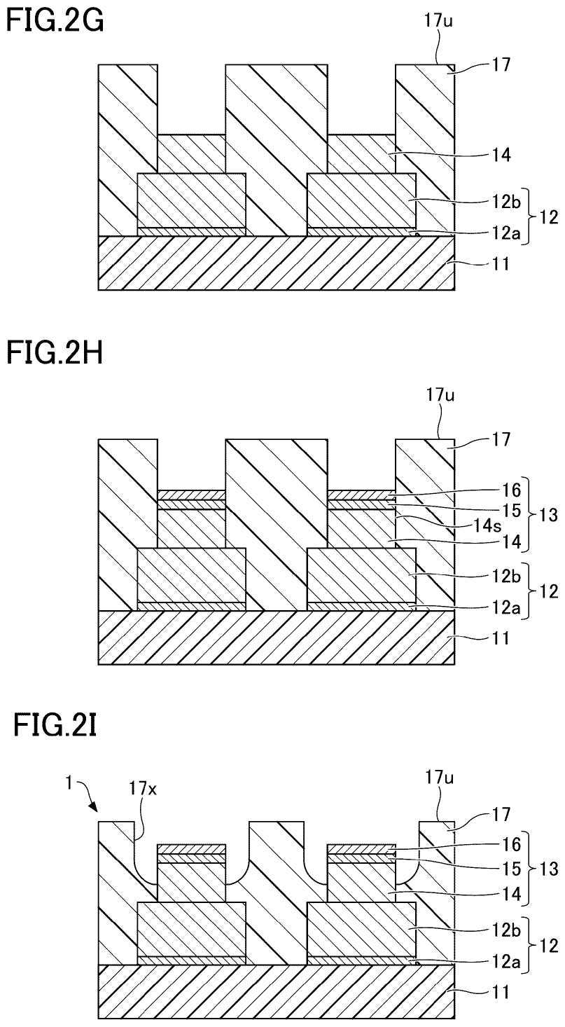

Next, a method of manufacturing a wiring substrate according to this embodiment is described. FIGS. 2A through 2I are diagrams illustrating a process of manufacturing a wiring substrate according to this embodiment.

First, in the process illustrated in FIG. 2A, the insulating layer 11 is prepared. Then, the seed layer 12a is formed on the upper surface of the insulating layer 11 by electroless plating or sputtering. Furthermore, the electroplating layer 12b is selectively formed on the seed layer 12a. Specifically, first, a plating resist layer with openings in areas where the electroplating layer 12b is to be formed is formed on the seed layer 12a. Then, the electroplating layer 12b is formed in the openings by electroplating that supplies power from the seed layer 12a. Thereafter, the plating resist layer is removed to complete the structure illustrated in FIG. 2A. The materials and thicknesses of the insulating layer 11, the seed layer 12a, and the electroplating layer 12b are as described above. The insulating layer 11 may be a multilayer wiring substrate in which multiple insulating layers and multiple wiring layers are stacked, an upper wiring layer and a lower wiring layer are electrically connected through vias, and external connection terminals are provided on a surface on the opposite side from a surface on which the insulating layer 17 is to be formed.

Next, in the process illustrated in FIG. 2B, a resist layer 300 to cover the seed layer 12a and the electroplating layer 12b is formed on the insulating layer 11. For example, a photosensitive dry film resist may be used as the resist layer 300. Then, the resist layer 300 is exposed to light and developed to form openings 300x that expose part of the upper surface of the electroplating layer 12b. The planar shape of the openings 300x may be, for example, circular.

Next, in the process illustrated in FIG. 2C, the first metal layer 14 is formed in the openings 300x. Specifically, for example, the first metal layer 14 is formed on the electroplating layer 12b exposed in the openings 300x by electroplating that supplies power from the seed layer 12a. The material of the first metal layer 14 is as described above. The first metal layer 14 is caused to have a sufficient thickness in view of polishing and etching as described below.

Next, in the process illustrated in FIG. 2D, the resist layer 300 is removed using a resist remover or the like. Then, the seed layer 12a exposed from (not covered with) the electroplating layer 12b is removed by wet etching or the like. As a result, the wiring layer 12 in which the electroplating layer 12b is stacked on the seed layer 12a is completed.

Next, in the process illustrated in FIG. 2E, the insulating layer 17 to cover the wiring layer 12 and the first metal layer 14 is formed on the insulating layer 11. Specifically, for example, a laminate of insulating resin in semi-cured film form is provided on the insulating layer 11 to cover the upper surface and the side surface of the wiring layer 12 and the upper surface and the side surface 14s of the first metal layer 14, and is cured into the insulating layer 17. Alternatively, in place of a laminate of insulating resin in semi-cured film form, for example, insulating resin in liquid or paste form may be applied and thereafter cured to form the insulating layer 17. The material of the insulating layer 17 is as described above. The insulating layer 17 may be thick enough to cover the upper surface of the first metal layer 14.

Next, in the process illustrated in FIG. 2F, the insulating layer 17 is polished on its upper surface 17u side to expose the upper surface of the first metal layer 14. The first metal layer 14 may be polished on its upper surface side when the insulating layer 17 is polished on its upper surface 17u side. For example, chemical mechanical polishing (CMP) may be employed for polishing. For example, the upper surface of the first metal layer 14 and the upper surface 17u of the insulating layer 17 may be flush with each other after polishing. Furthermore, in the case of polishing the first metal layer 14 on its upper surface side when the insulating layer 17 is polished on its upper surface 17u side, the first metal layer 14 may be constant in height because of CMP process even when the first metal layer 14 formed in the process illustrated in FIG. 2C varies in height.

Next, in the process illustrated in FIG. 2G, an upper portion of the first metal layer 14 is removed to cause the upper surface of the first metal layer 14 to be positioned lower than the upper surface 17u of the insulating layer 17. The upper portion of the first metal layer 14 may be removed by, for example, wet etching. When the first metal layer 14 is copper, for example, aqueous ferric chloride solution, aqueous cupric chloride solution, aqueous ammonium persulfate solution or the like may be used for etching.

Next, in the process illustrated in FIG. 2H, the second metal layer 15 and the third metal layer 16 are sequentially stacked on the upper surface of the first metal layer 14 to form the protruding electrodes 13. For example, first, a nickel (Ni) layer is formed on the upper surface of the first metal layer 14 as the second metal layer 15 by electroless plating. Next, a palladium layer and a gold layer are sequentially formed as the third metal layer 16 on the upper surface of the second metal layer 15 by electroless plating. The entirety of the side surface 14s of the first metal layer 14 is covered with the insulating layer 17. Therefore, the second metal layer 15 and the third metal layer 16 are formed on only the upper surface of the first metal layer 14.

Next, in the process illustrated in FIG. 2I, the recesses 17x are formed in the upper surface 17u of the insulating layer 17. The recesses 17x may be formed by, for example, isotropic plasma etching. According to isotropic plasma etching, an etching reaction occurs in all directions, so that the insulating layer 17 is etched for the same amount between the upper surface 17u of the insulating layer 17 and the side surface of each protruding electrode 13 to form the recesses 17x. The recesses 17x cannot be formed by anisotropic plasma etching, according to which an etching reaction occurs only in a particular direction.

The recesses 17x may be, for example, circular in a plan view. Part of the protruding electrode 13 is exposed in each recess 17x. Specifically, a lower part of the first metal layer 14 is buried in the insulating layer 17, and an upper part of the first metal layer 14, the second metal layer 15, and the third metal layer 16 protrude in the recesses 17x. The insulating layer 17 is thinner than in the process illustrated in FIG. 2H. The upper surface of the third metal layer 16 is positioned lower than the upper surface 17u of the insulating layer 17. Through the above-described process, the wiring substrate 1 is completed.

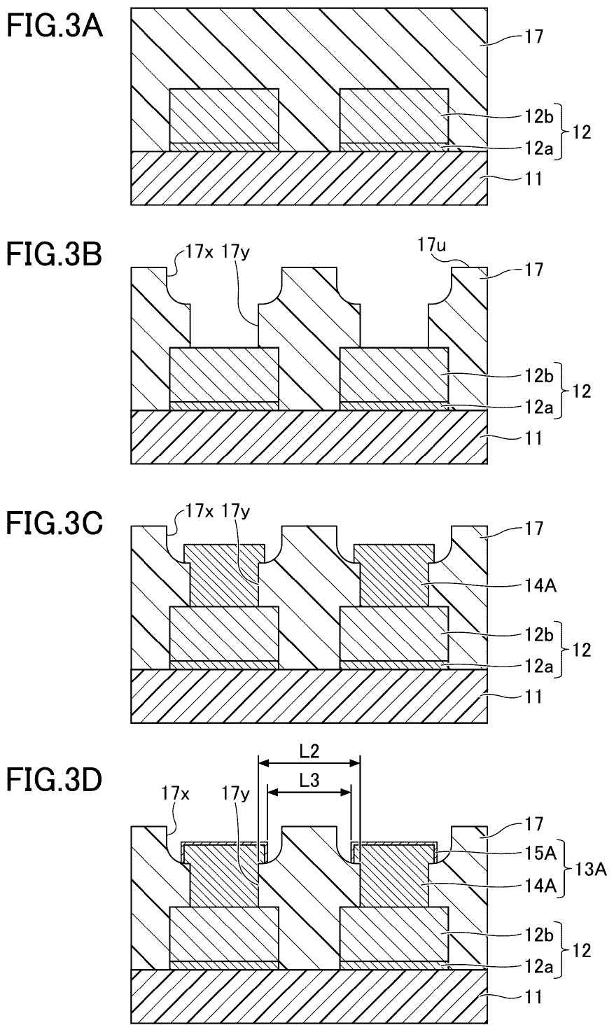

FIGS. 3A through 3D are diagrams illustrating a process of manufacturing a wiring substrate according to a comparative example. First, in the process illustrated in FIG. 3A, the wiring layer 12 is formed on the insulating layer 11, and the insulating layer 17 to cover the wiring layer 12 is further formed.

Next, in the process illustrated in FIG. 3B, the insulating layer 17 is exposed to light and developed to form the recesses 17x in the upper surface 17u of the insulating layer 17. Then laser light is emitted into the recesses 17x to form through holes 17y that communicate with the recesses 17x. The recesses 17x are, for example, circular in a plan view, and the through holes 17y are, for example, circular with a diameter smaller than the diameter of the recesses 17x in a plan view. The upper surface of the wiring layer 12 is exposed in the through holes 17y.

Next, in the process illustrated in FIG. 3C, a first metal layer 14A is formed in the through holes 17y and the recesses 17x. Specifically, for example, the through holes 17y are filled by electroless plating to form a nickel layer as the first metal layer 14A that extends into the recesses 17x. The first metal layer 14A isotropically grows by electroless plating. Therefore, the first metal layer 14A extending into the recesses 17x laterally extends along the inside surface of the recesses 17x.

Next, in the process illustrated in FIG. 3D, a second metal layer 15A to cover the first metal layer 14A protruding in the recesses 17x is formed to form protruding electrodes 13A. Specifically, for example, a palladium layer and a gold layer are sequentially formed as the second metal layer 15A on the upper surface and the side surface of the first metal layer 14A by electroless plating. As a result, a wiring substrate according to the comparative example is completed.

According to the wiring substrate of the comparative example, with respect to each protruding electrode 13A, the part protruding in the corresponding recess 17x is wider than the part buried in the insulating layer 17 in a sectional view. According to the wiring substrate of the comparative example, with respect to the protruding electrodes 13A, while the interval between their respective parts covered with the insulating layer 17 is L2, the interval between their respective parts protruding in the recesses 17x is L3. That is, while the interval between the protruding electrodes 13A by design is L2, the actual interval between the protruding electrodes 13A is L3, which is smaller than the design value. Therefore, the adjacent protruding electrodes 13A may be short-circuited when a semiconductor element is connected to the protruding electrodes 13A. This is explained in detail below.

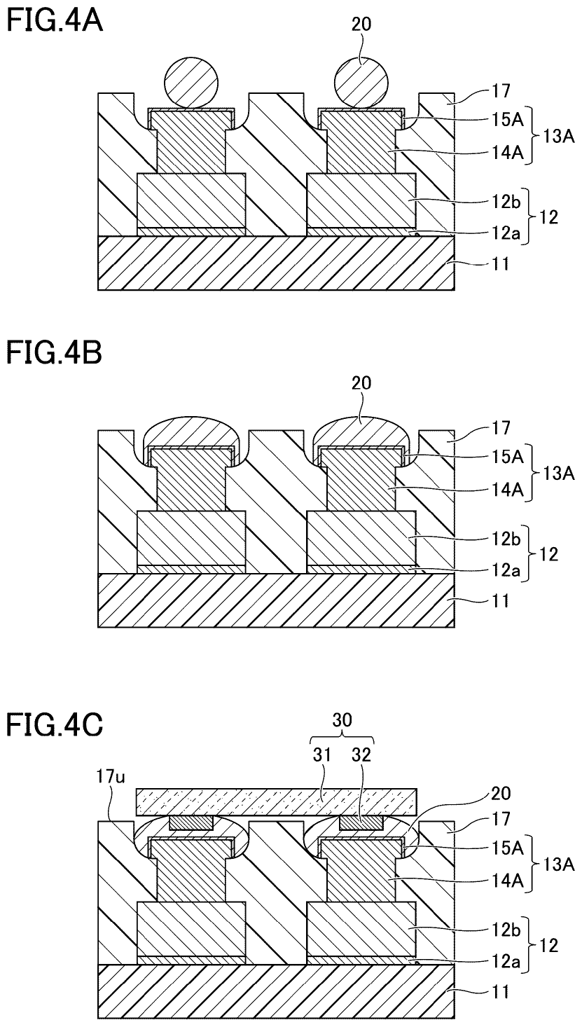

A process of connecting a semiconductor element to protruding electrodes is, for example, as illustrated in FIGS. 4A through 4C. First, in the process illustrated in FIG. 4A, joining parts 20 are placed on the second metal layer 15A of the protruding electrodes 13A. Next, in the process illustrated in FIG. 4B, reflow soldering is performed to form the joining parts 20 that cover the upper surface and the side surface of the second metal layer 15A. The joining parts 20 are, for example, solder. Examples of solder materials that may be used include alloys including lead (Pb), alloys of tin (Sn) and copper, alloys of tin and silver (Ag), and alloys of tin, silver and copper.

Next, in the process illustrated in FIG. 4C, a semiconductor element 30 including a semiconductor substrate 31 and electrodes 32 is prepared, and the electrodes 32 and the protruding electrodes 13A are joined by the joining parts 20. As illustrated in FIG. 3D, the interval L3 between the adjacent protruding electrodes 13A is smaller than the design value. Therefore, in the process illustrated in FIG. 4C, the joining parts 20 may overflow onto the upper surface 17u of the insulating layer 17. In this case, the adjacent protruding electrodes 13A may be short-circuited.

In contrast, according to the wiring substrate 1, as illustrated in, for example, FIG. 1, with respect to the protruding electrodes 13, the part covered with the insulating layer 17 and the part protruding from the insulating layer 17 are equal in width, and no part laterally extends to reduce the interval between the adjacent protruding electrodes 13. That is, the interval L1 between the protruding electrodes 13 illustrated in FIG. 1 is as designed.

That is, according to the wiring substrate 1, the interval L1 between the adjacent protruding electrodes 13 is never smaller than the design value. Therefore, in the case of joining the protruding electrodes 13 and the electrodes 32 of the semiconductor element 30 together in the same manner as illustrated in FIGS. 4A through 4C, it is possible to reduce the possibility that the adjacent protruding electrodes 13 are short-circuited by overflowing solder.

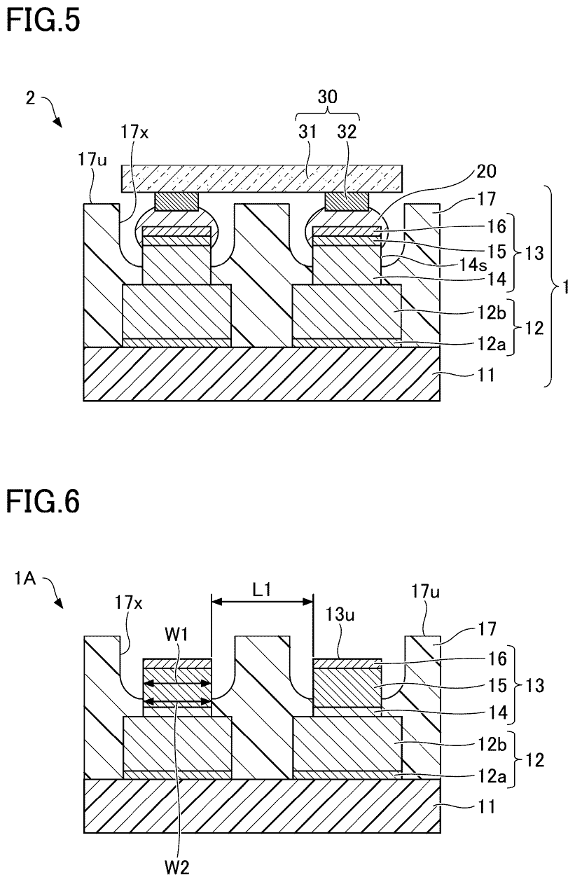

FIG. 5 is a sectional view of a semiconductor device according to this embodiment. A semiconductor device 2 illustrated in FIG. 5 includes the wiring substrate 1 illustrated in FIG. 1 and the semiconductor element 30 mounted on the wiring substrate 1. The protruding electrodes 13 of the wiring substrate 1 and the electrodes 32 of the semiconductor element 30 are electrically connected by the conductive joining parts 20.

As described above, according to the wiring substrate 1, each protruding electrode 13 has a constant width and includes no part that would reduce the interval between the adjacent protruding electrodes 13. Therefore, the joining parts 20 are unlikely to overflow to short-circuit the adjacent protruding electrodes 13.

Furthermore, the second metal layer 15 and the third metal layer 16, which have good solder wettability, are formed only on the upper surface and not on the side surface 14s of the first metal layer 14. Therefore, the joining parts 20 are more likely to be formed on the second metal layer 15 and the third metal layer 16 with good solder wettability and are less likely to be formed on the side surface 14s of the first metal layer 14. Therefore, the joining parts 20 are less likely to laterally extend. In particular, when the side surface 14s of the first metal layer 14 is oxidized, the joining parts 20 are less likely to be formed. Because it is possible to prevent the joining parts 20 from flowing into the recesses 17x, the joining parts 20 are more likely to be kept constant in height.

Furthermore, the recesses 17x are formed to be so deep as to expose part of the side surface 14s of the first metal layer 14. Therefore, even if the amount of the joining parts 20 becomes excessive for some reason so that the joining parts 20 flow onto the side surface 14s of the first metal layer 14, on which solder is less likely to be wet, the presence of an area where an excess of the joining part 20 is stored at the bottom of each recess 17x can prevent the joining parts 20 from flowing toward the upper surface 17u of the insulating layer 17.

The joining parts 20 are preferably positioned lower than the upper surface 17u of the insulating layer 17. This can further reduce the possibility that the joining parts 20 flow toward the upper surface 17u of the insulating layer 17.

Next, a variation of the embodiment is described. The variation is different from the embodiment in the thickness of metal layers of the protruding electrode. In the following description of the variation, description of the same elements or configurations as those of the above-described embodiment may be omitted.

FIG. 6 is a sectional view of a wiring substrate according to the variation. Referring to FIG. 6, a wiring substrate 1A according to the variation is different from the wiring substrate 1 in that the first metal layer 14 is thinner and the second metal layer 15 is thicker in the protruding electrodes 13.

According to the wiring substrate 1A, in the protruding electrodes 13, a lower portion of the second metal layer 15 and the first metal layer 14 are buried in the insulating layer 17 and an upper portion of the second metal layer 15 and the third metal layer 16 protrude in the recesses 17x. In the wiring substrate 1A, the thickness of the entirety of each protruding electrode 13 and the interval L1 between the protruding electrodes 13 are the same as those in the wiring substrate 1, and the upper surface 13u of each protruding electrode 13 is positioned lower than the upper surface 17u of the insulating layer 17. In each protruding electrode 13, the width W1 of the part protruding in the recess 17x is equal to the width W2 of the part buried in the insulating layer 17 in a sectional view.

Thus, in the protruding electrodes 13, the first metal layer 14 does not necessarily have to protrude in the recesses 17x and the second metal layer 15 and the third metal layer 16 may protrude in the recesses 17x. In this case as well, the same effects as in the above-described embodiment are achieved.

All examples and conditional language provided herein are intended for pedagogical purposes of aiding the reader in understanding the invention and the concepts contributed by the inventors to further the art, and are not to be construed as limitations to such specifically recited examples and conditions, nor does the organization of such examples in the specification relate to a showing of the superiority or inferiority of the invention. Although one or more embodiments of the present invention have been described in detail, it should be understood that the various changes, substitutions, and alterations could be made hereto without departing from the spirit and scope of the invention.

Various aspects of the subject-matter described herein may be set out non-exhaustively in the following numbered clauses:

1. A method of manufacturing a wiring substrate, the method including:
forming an insulating layer covering a protruding electrode;
polishing the insulating layer on its upper surface side to expose the upper surface of the protruding electrode from the insulating layer;
removing a portion of the protruding electrode on its upper surface side to cause the upper surface of the protruding electrode to be lower than the upper surface of the insulating layer; and
forming a recess in the upper surface of the insulating layer,
wherein a width of a part of the protruding electrode protruding in the recess is equal to a width of a part of the protruding electrode buried in the insulating layer, and
the upper surface of the protruding electrode is positioned lower than the upper surface of the insulating layer.

2. The method of clause 1, wherein the recess is formed by isotropic plasma etching.

What is claimed is:

1. A wiring substrate comprising:
an insulating layer, the insulating layer having a recess formed in a surface of the insulating layer; and
a protruding electrode partly buried in the insulating layer to protrude in the recess,
wherein a width of the protruding electrode is constant in a sectional view of the protruding electrode, and
a surface of the protruding electrode facing in the same direction as the surface of the insulating layer is closer to a bottom of the recess than is the surface of the insulating layer.

2. The wiring substrate as claimed in claim 1, wherein
the protruding electrode includes a first part buried in the insulating layer and a second part extending from the first part and protruding in the recess, and
a width of the first part is equal to a width of the second part in the sectional view of the protruding electrode.

3. The wiring substrate as claimed in claim 2, wherein an entirety of a side surface of the second part is exposed in the recess.

4. The wiring substrate as claimed in claim 3, wherein there is a space between the entirety of the side surface of the second part and an inside surface of the recess.

5. The wiring substrate as claimed in claim 1, wherein
the protruding electrode includes
a first metal layer including a first portion buried in the insulating layer and a second portion extending from the first portion and protruding in the recess; and
a second metal layer stacked on the second portion of the first metal layer and absent on a side surface of the first metal layer.

6. The wiring substrate as claimed in claim 5, wherein
the first metal layer is a copper layer, and
the second metal layer is a nickel layer.

7. The wiring substrate as claimed in claim 5, wherein the protruding electrode further includes a third metal layer stacked on the second metal layer and absent on a side surface of the second metal layer.

8. The wiring substrate as claimed in claim 7, wherein the third metal layer includes a gold layer.

9. The wiring substrate as claimed in claim 7, wherein the third metal layer is a laminate of a gold layer and a palladium layer.

10. The wiring substrate as claimed in claim 5, wherein a width of the first metal layer is constant and is equal to a width of the second metal layer, in the sectional view of the protruding electrode.

11. The wiring substrate as claimed in claim 1, wherein
the protruding electrode includes
a first metal layer buried in the insulating layer; and
a second metal layer including a first portion stacked on the first metal layer and buried in the insulating layer and a second portion extending from the first portion and protruding in the recess.

12. The wiring substrate as claimed in claim 11, wherein
the first metal layer is a copper layer, and
the second metal layer is a nickel layer.

13. The wiring substrate as claimed in claim 11, wherein the protruding electrode further includes a third metal layer stacked on the second portion of the second metal layer and absent on a side surface of the second portion.

14. The wiring substrate as claimed in claim 13, wherein the third metal layer includes a gold layer.

15. The wiring substrate as claimed in claim 13, wherein the third metal layer is a laminate of a gold layer and a palladium layer.

16. The wiring substrate as claimed in claim 11, wherein a width of the second metal layer is constant in the sectional view of the protruding electrode.

17. A semiconductor device comprising:
the wiring substrate as set forth in claim 1;
a semiconductor element mounted on the wiring substrate, the semiconductor element including an electrode; and
a conductive joining part electrically connecting the protruding electrode and the electrode, the conductive joining part being positioned closer to the bottom of the recess than is the surface of the insulating layer.
